(19) United States
(12) Patent Application Publication
(10) Pub. No.: US 2014/0008693 A1
(43) Pub. Date: Jan. 9, 2014

(54) LIGHT-EMITTING DEVICE AND LEAD FRAME STRIP

(71) Applicant: DOW CORNING TAIWAN INC., TAIPEI (TW)

(72) Inventor: YA-CHING FENG, HSINCHU COUNTY (TW)

(21) Appl. No.: 13/933,546

(22) Filed: Jul. 2, 2013

(30) Foreign Application Priority Data
Jul. 4, 2012 (TW) 101212884

(51) Int. Cl. H01L 33/62; H01L 23/495

(52) U.S. Cl. CPC H01L 33/62; H01L 23/49541
USPC 257/99; 257/773

(57) ABSTRACT

A light-emitting device in one embodiment comprises a lead frame, an adhesive, and a light-emitting element. The lead frame comprises two conductive members. The two conductive members are separated by a gap. Each conductive member comprises an upper surface and a lower surface. The upper surface and the lower surface are opposite to each other. The adhesive fills the gap and partially covers the upper and lower surfaces of each conductive member. The light-emitting element is disposed on the upper surface of one conductive member. The light-emitting element electrically connects the two conductive members.

### CROSS-REFERENCE TO RELATED APPLICATION

The present application is based on, and claims priority from, Taiwan Patent Application Serial Number 101212884, filed on Jul. 4, 2012, the disclosure of which is hereby incorporated by reference herein in its entirety.

### BACKGROUND

1. Technical Field

The present invention relates to a light-emitting device and a lead frame strip.

2. Related Art

FIG. 1 shows a current light-emitting device 1. As shown in FIG. 1, the light-emitting device 1 comprises two electrodes 11. The two electrodes 11 are separated by a slit, in which an insulation glue 12 is filled to fasten the two electrodes 11. A light-emitting diode 13 is fixed on one electrode 11 and electrically connects the two electrodes 11. A reflective cup 14 formed on the two electrodes 11 surrounds the light-emitting diode 13 and is used to outwardly project light from the light-emitting diode 13. The reflective cup 14 is filled with transparent glue 15, which can be added with a fluorescent substance.

Normally, the electrode 11 are designed to be thin so that the joint surfaces of the insulation glue 12 and the electrode 11 can be smaller. As a result, the two electrodes 11 cannot be securely fixed together and will be easily separated from each other when a force is applied. In addition, as shown in FIG. 1, the bonding interface between the electrode 11 and the insulation glue 12 extends to the bottom of the electrode 11, which forms a path that allows environmental moisture to enter into the light-emitting device 1. Since the interface between the electrode 11 and the insulation glue 12 is short, moisture can easily enter and adversely affect the performance of the light-emitting device 1.

### SUMMARY

A light-emitting device of one embodiment of the present invention comprises a lead frame, an adhesive, and a light-emitting element. The lead frame comprises two conductive members. The two conductive members are separated by a gap. Each conductive member comprises an upper surface and a lower surface. The upper surface and the lower surface are opposite to each other. The adhesive fills the gap and partially covers the upper and lower surfaces of each conductive member. The light-emitting element is disposed on the upper surface of one conductive member. The light-emitting element electrically connects the two conductive members.

A lead frame strip of one embodiment of the present invention comprises a plurality of lead frames. Each lead frame comprises two conductive members and an adhesive. The two conductive members are separated by a gap. Each conductive member comprises an upper surface and a lower surface. The upper surface and the lower surface are opposite to each other. The adhesive fills the gap between the two conductive members of each lead frame. The adhesive partially covers the upper and lower surface of each conductive member of each lead frame.

To provide a better understanding of the above-described objectives, characteristics and advantages of the present invention, a detailed explanation is provided in the following embodiments with reference to the drawings.

### BRIEF DESCRIPTION OF THE DRAWINGS

The invention will be described according to the appended drawings in which:

FIG. 1 shows a current light-emitting device;

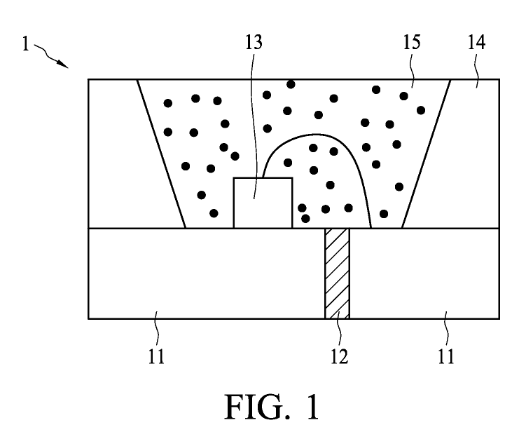

FIG. 2 is a schematic view showing a light-emitting device according to one embodiment of the present invention;

FIG. 3 is a schematic view showing a light-emitting device according to another embodiment of the present invention;

FIG. 4 is a schematic view showing the recess on the upper surface of a conductive member according to one embodiment of the present invention;

FIG. 5 is a schematic view showing the recess on the upper surface of a conductive member according to another embodiment of the present invention;

FIG. 6 is a schematic view showing the recess on the lower surface of a conductive member according to another embodiment of the present invention;

FIG. 7 is a schematic view showing a lead frame strip according to one embodiment of the present invention;

FIG. 8 is a cross-sectional view along line 8-8 of FIG. 7;

FIG. 9 is a schematic view showing a lead frame strip according to another embodiment of the present invention;

FIG. 10 is a schematic view showing a lead frame strip according to another embodiment of the present invention;

FIG. 11 is a cross-sectional view along line 11-11 of FIG. 10; and

FIG. 12 is a schematic view showing a lead frame strip 10a according to another embodiment of the present invention.

### DETAILED DESCRIPTION OF DISCLOSED EMBODIMENTS

The following description is presented to enable any person skilled in the art to make and use the disclosed embodiments, and is provided in the context of a particular application and its requirements. Various modifications to the disclosed embodiments will be readily apparent to those skilled in the art, and the general principles defined herein may be applied to other embodiments and applications without departing from the spirit and scope of the disclosed embodiments. Thus, the disclosed embodiments are not limited to the embodiments shown, but are to be accorded the widest scope consistent with the principles and features disclosed herein.

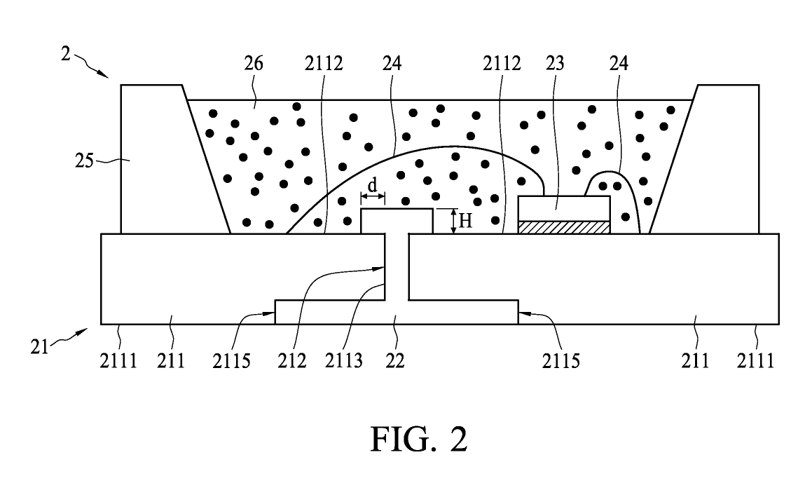

FIG. 2 is a schematic view showing a light-emitting device 2 according to one embodiment of the present invention. Referring to FIG. 2, the light-emitting device 2 comprises a lead frame 21, an adhesive 22, and a light-emitting element 23. The lead frame 21 comprises two conductive members 211. The two conductive members 211 are separated by a gap 212 to prevent the electrical connection between the two conductive members 211 and to avoid the occurrence of a short circuit. The adhesive 22 may comprise a polymer. The adhesive 22 is configured to fill the gap 212 to fasten the two conductive members 211 together. The light-emitting element 23 is disposed on one conductive member 211 and electrically connects the two conductive members 211 in a respective manner.

In one embodiment, wires 24 are utilized to electrically connect the light-emitting element 23 and the two conductive members 211. In another embodiment, bumps are used to electrically connect the light-emitting element 23 and the two conductive members 211. In another embodiment, the light-emitting element 23 is disposed on and electrically connected to one conductive member 211, and then electrically connected to another conductive member 211 through a wire.

In one embodiment, the two conductive members 211 are adapted for external power supply to the light-emitting element 23. In one embodiment, one of the two conductive members 211 are formed to support the light-emitting element 23.

In one embodiment, the lead frame 21 can have a high thermal conductivity to facilitate heat dissipation. In one embodiment, the thermal conductivity of the lead frame 21 can be greater than 400 W/mK. In one embodiment, the thermal conductivity of the lead frame 21 can be between 300 W/mK and 400 W/mK. In one embodiment, when heat is not a critical issue, the lead frame 21 can have a thermal conductivity of less than 300 W/mK.

The lead frame 21 can be formed by etching or stamping a metal sheet. The lead frame 21 can be a conductor. In one embodiment, the lead frame 21 comprises metal. In one embodiment, the lead frame 21 comprises alloy. In one embodiment, the lead frame 21 comprises nickel iron alloy or copper alloy. In one embodiment, the lead frame 21 comprise clad materials such as cooper clad stainless steel or the like. In one embodiment, the lead frame 21 comprises metal-coated material such as silver plated with copper or the like. In addition, the lead frame 21 can be made of materials other than metal. In one embodiment, the lead frame 21 comprises silicon.

The adhesive 22 is used to secure the two conductive members 211. In one embodiment, the adhesive 22 can be applied to secure the two conductive members 211 using an insert-molding, injection-molding, transfer-molding, or compression-molding process.

Each conductive member 211 comprises a lower surface 2111 and an upper surface 2112 opposite to the lower surface 2111. The light-emitting element 23 is disposed on the upper surface 2112 of one conductive member 211. The adhesive 22 fills the gap 212 and extends toward the two conductive members 211 and partially covers the lower and upper surfaces 2111 and 2112 of each conductive member 211. Because the adhesive 22 extends to adhere to the lower and upper surface 2111 and 2112, the joint surfaces of the adhesive 22 and the lead frame 21 can be increased so that the bonding force between the adhesive 22 and the lead frame 21 can be increased, and the possibility of separation of the adhesive 22 from the lead frame 21 can be reduced. The adhesion of the adhesive 22 to the upper surface 2112 can prevent the separation of the adhesive 22 from an edge surface 2113 of the conductive member 211 defining the gap 212 when the lead frame 21 is bent upward. Furthermore, the extension of the adhesive 22 on the lower and upper surfaces 2111 and 2112 can increase the length of the bonding interface between the adhesive 22 and the lead frame 21 so that environmental moisture cannot easily diffuse into the light-emitting device 2 through the bonding interface, thereby affecting the performance of the light-emitting device 2.

As shown in FIG. 2, in one embodiment, the adhesive 22 can be formed to protrude from the upper surfaces 2112 of the conductive members 211. In one embodiment, the adhesive 22 protrudes from the upper surface 2112 of the conductive member 211 to a thickness of not less than ten micrometers. In one embodiment, the adhesive 22 protrudes from the upper surface 2112 of the conductive member 211 to a thickness of from 25 micrometers to 35 micrometers. In one embodiment, the adhesive 22 protrudes from the upper surface 2112 of the conductive member 211 to a thickness of not less than 30 micrometers. When the adhesive 22 protrudes from the upper surface 2112 of the conductive member 211 to a thickness of more than ten micrometers, the protruding portion may not be easily compromised in the following processes.

Referring to FIG. 2 again, the adhesive 22 extends from a location above the gap 212 toward the upper surfaces 2112 of the conductive members 211 and partially covers the upper surface 2112 of each conductive member 211. In one embodiment, the adhesive 22 extends from a location of the gap 212 onto the upper surface 2112 to a distance “d” of not less than one micrometer. In one embodiment, the adhesive 22 extends from the gap 212 onto the upper surface 2112 to a distance “d” of not less than five micrometers.

The adhesive 22 can be used to maintain the shape of the lead frame 21. The adhesive 22 can be formed with a predetermined shape. In the present invention, the cross section of the adhesive 22 has an I shape.

The adhesive 22 can cover a large region of the lower surface 2111 so that the bonding strength can be increased. In one embodiment, the lower surface 2111 of each conductive member 211 is formed with a recess 2115, and the adhesive 22 covering the lower surface 2111 fills the recess 2115.

In one embodiment, the adhesive 22 is an insulation material. The adhesive 22 can have a high reflectivity so that it can reflect light from the light-emitting element 23. The adhesive 22 may be white. In one embodiment, the adhesive 22 may comprise a resin. In one embodiment, the adhesive 22 may comprise silicone. In one embodiment, the adhesive 22 may comprise a liquid crystal polymer, a polyimide-based polymer, or the like.

Referring back to the FIG. 2, the light-emitting device 2 may further comprise a reflector 25 configured to outwardly project light from the light-emitting element 23. The reflector 25 can be disposed on the lead frame 21 and configured to surround the light-emitting element 23. The reflector 25 can be made of a white resin of high reflectivity. In one embodiment, the reflector 25 can be white. In one embodiment, the reflector 25 may comprise a resin. In one embodiment, the reflector 25 may comprise silicone. In one embodiment, the reflector 25 may comprise a liquid crystal polymer, a polyimide-based polymer, or the like. In one embodiment, the reflector 25 may comprise one of other types of resin or a ceramic material.

The reflector 25 defines a receiving space, and a resin 26 is disposed in the receiving space, covering the light-emitting element 23. The resin 26 can protect the light-emitting element 23 and the wires 24. The resin 26 can allow light to pass through without resistance or diffusion, or with slight resistance or diffusion. The resin 26 can be transparent. The resin 26 can have any shapes including a lens shape. In one embodiment, the resin 26 can be mixed with a material that can scatter light. In one embodiment, the resin 26 can be mixed with a material that can generate complementary light so that the light-emitting device 2 can emit mixed light.

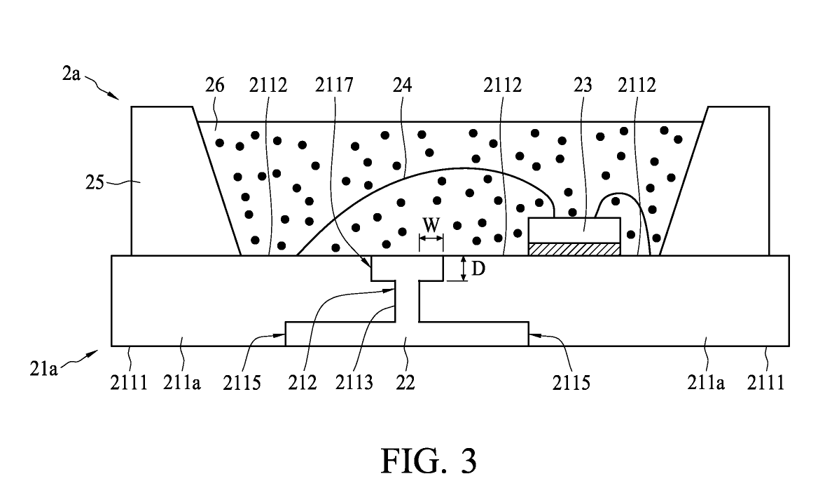

FIG. 3 is a schematic view showing a light-emitting device 2a according to another embodiment of the present invention. The light-emitting device 2a of the embodiment shown in FIG. 3 is similar to the light-emitting device 2 of the embodiment shown in FIG. 2. The primary difference between the two embodiments is that the lead frame 21a of the light-emitting device 2a has a different structure. Referring to FIG. 3, the lead frame 21a comprises two conductive members 211a, which are separated by a gap 212. Each conductive member 211a comprises a lower surface 2111 and an upper surface 2112. The lower surface 2111 of each conductive member 211a is formed with a recess 2115, and the upper surface 2112 of each conductive member 211a is formed with a recess 2117 as well. The adhesive 22 fills the gap 212 and the two recesses 2115 and 2117. Thus, the adhesive 22 covers a portion of the upper surface 2112 and a portion of the lower surface 2111.

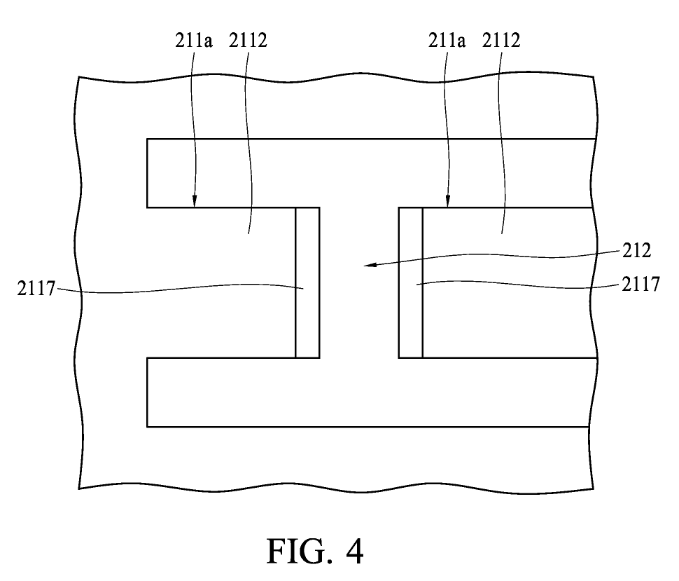

Referring to FIG. 4, the recess 2117 can be formed along the gap 212. Moreover, as shown in FIG. 3, in one embodiment, the width W of the recess 2117, measured along a direction from the gap toward a corresponding conductive member 211a, is not less than one micrometer. In one embodiment, the width W of the recess 2117, measured along a direction from the gap toward a corresponding conductive member 211a, is not less than five micrometers. In one embodiment, the depth D of the recess 2117 may not be less than ten micrometers. In one embodiment, the depth D of the recess 2117 may be between 25 micrometers and 35 micrometers. In one embodiment, the depth D of the recess 2117 may be 30 micrometers. In one embodiment, due to being located in the recess 2117, the adhesive 22 on the upper surface 2112 is not easily damaged, and therefore the depth D of the recess 2117 can be less than 30 micrometers.

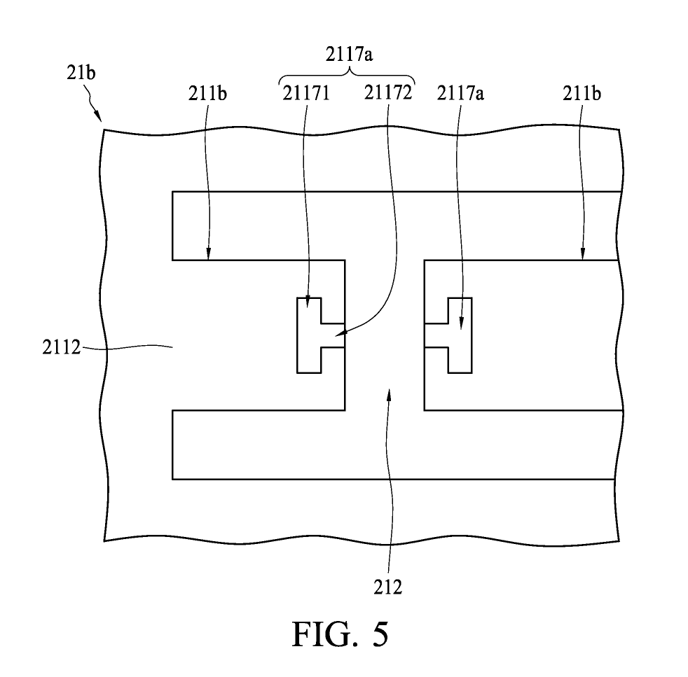

FIG. 5 is a schematic view showing the recess 2117a on the upper surface 2112 of a conductive member 211b according to another embodiment of the present invention. The recess formed on the upper surface of a conductive member can have an arbitrary shape. In one embodiment, the recess on the upper surface of a conductive member may comprise a curve. In one embodiment, the recess on the upper surface of a conductive member may comprise an arc. The recess of an arbitrary shape can occupy a larger area of the upper surface 2112. Thus, the bonding strength between the lead frame and the adhesive can be increased; and the amount of the adhesive on the upper surface of the lead frame can be similar to that of the adhesive on the lower surface of the lead frame in order to avoid warpage after the adhesive is formed. In one embodiment, the recess 2117a on the upper surface 2112 of the conductive member 211b may comprise a front section 21171 and a neck 21172. The neck 21172 is configured to connect the front section 21171 and the gap 212, and therefore the adhesive can fill the front section 21171 through the neck 21172.

In one embodiment, the neck 21172 extends from the gap 212 to the upper surface 2112, and the front section 21171 transversely extends relative to the extension direction of the neck 21172.

The front section 21171 can have an arbitrary shape. In one embodiment, the front section 21171 can have an elongated shape. In one embodiment, the recess 2117a can have a T shape. In one embodiment, the recess 2117a can have an L shape.

In one embodiment, the recesses on the upper surfaces of two conductive members can have the same shape. In another embodiment, the recesses on the upper surfaces of two conductive members can have different shapes.

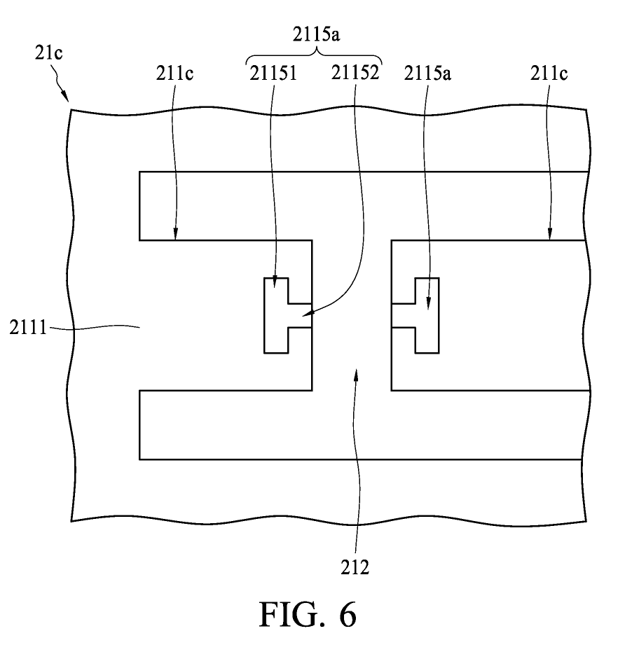

FIG. 6 is a schematic view showing the recess 2115a on the lower surface 2111 of a conductive member 211c according to another embodiment of the present invention. Similarly, the recess 2115a on the lower surface 2111 of a conductive member 211c can have an arbitrary shape. In one embodiment, the recess 2115a on the lower surface 2111 of a conductive member 211c may comprise a front section 21151 and a neck 21152, wherein the neck 21152 connects the front section 21151 and the gap 212. In one embodiment, the front section 21151 can transversely extend relative to the extension direction of the neck 21152.

The front section 21151 can have an arbitrary shape. In one embodiment, the front section 21151 can have an elongated shape. In one embodiment, the recess 2115a can have a T shape. In one embodiment, the recess 2115a can have an L shape.

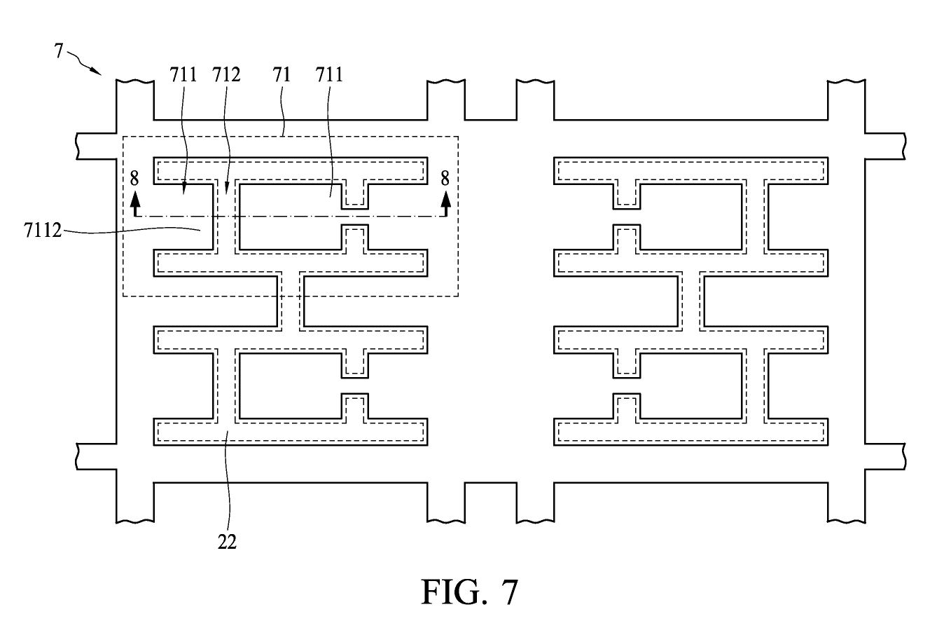

FIG. 7 is a schematic view showing a lead frame strip 7 according to one embodiment of the present invention. As shown in FIG. 7, the lead frame strip 7 comprises a plurality of lead frames 71. Each lead frame 71 comprises two conductive members 711, wherein one conductive member 711 is configured as an electrode for a light-emitting element, and another conductive member 711 is configured to support the light-emitting element and as an electrode for the light-emitting element as well.

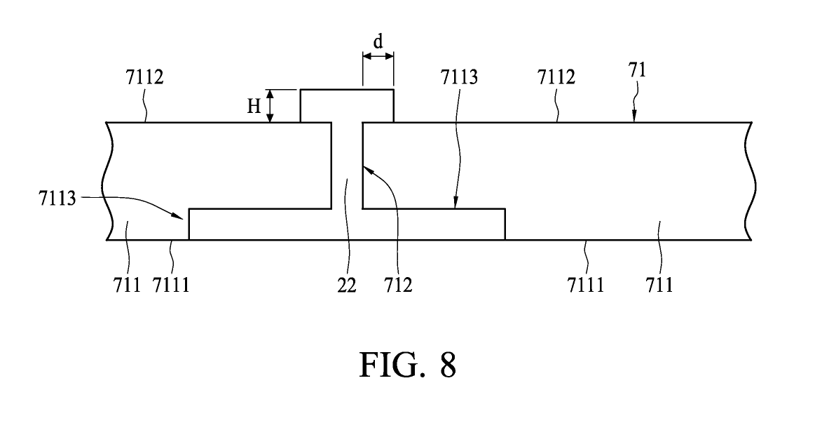

As shown in FIGS. 7 and 8, the two conductive members 711 are separated by a gap 712. The adhesive 22 fills the gap 712 and partially covers a lower surface 7111 and an upper surface 7112 opposite to the lower surface 7111.

The adhesive 22 may protrude from the upper surface 7112 of the lead frame 71. In one embodiment, the adhesive 22 protrudes from the upper surface 7112 to a thickness of not less than ten micrometers. In one embodiment, the adhesive 22 protrudes from the upper surface 7112 to a thickness between 25 micrometers and 35 micrometers. In one embodiment, the adhesive 22 protrudes from the upper surface 7112 to a thickness of not less than 30 micrometers.

Referring back to FIG. 7, in one embodiment, the adhesive 22 is configured to cover all edge regions of the conductive member 711. In one embodiment, the adhesive 22 can cover a portion of the edge regions of the conductive member 711 when the bonding strength is sufficient. In one embodiment, the adhesive 22 can cover the part of the edge regions of the conductive member 711 where the ingress of moisture can lead to serious problems.

As shown in FIG. 8, the adhesive 22 extends from the gap 712 toward the lead frame 71, partially covering the upper surface 7112 of each conductive member 711. In one embodiment, the adhesive 22 extends from the gap 712 onto the upper surface 7112 to a distance “d” of not less than one micrometer. In one embodiment, the adhesive 22 extends from the gap 712 onto the upper surface 7112 to a distance “d” of not less than five micrometers.

As shown in FIG. 8, the lower surface 7111 of each conductive member 711 is formed with a recess 7113. The adhesive 22 on the lower surface 7111 of each conductive member 711 is disposed in the recess 7113. The recess 7113 can have an arbitrary shape, as mentioned above. In one embodiment, the recess 7113 can comprise a curve. In one embodiment, the recess 7113 can comprise an arc. In one embodiment, the recess 7113 is rectangular. In one embodiment, the recess 7113 comprises a front section and a neck, wherein the neck connects the front section and gap 712. In one embodiment, the recess 7113 comprises a T shape. In one embodiment, the recess 7113 comprises an L shape. In one embodiment, within a lead frame 71, the recesses 7113 on the lower surfaces 7111 of two conductive members 711 can have the same shape. In one embodiment, within a lead frame 71, the recesses 7113 on the lower surfaces 7111 of two conductive members 711 can have different shapes.

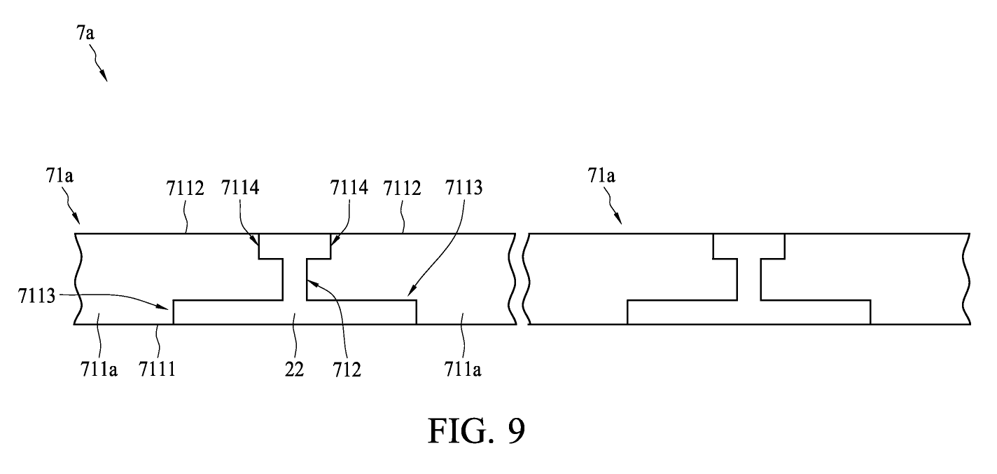

FIG. 9 is a schematic view showing a lead frame strip 7a according to another embodiment of the present invention. As shown in FIG. 9, the lead frame strip 7a comprises a plurality of lead frames 71a. Each lead frame 71a comprises two conductive members 711a. Each conductive member 711a comprises a lower surface 7111 and an upper surface 7112. A recess 7113 is formed on the lower surface 7111 of each conductive member 711a, and a recess 7114 is formed on the upper surface 7112 of each conductive member 711a. The adhesive 22 fills the gap 712 between the two conductive members 711a and additionally fills the recesses 7113 and 7114.

The recess 7114 can have an arbitrary shape. In one embodiment, the recess 7114 comprises a curve. In one embodiment, the recess 7114 comprises an arc. In one embodiment, the recess 7114 is rectangular. In one embodiment, the recess 7114 comprises a front section and a neck, wherein the neck connects the front section and the gap 712. In one embodiment, the recess 7114 has a T shape. In one embodiment, the recess 7114 has an L shape. In one embodiment, within a lead frame 71a, the recesses 7114 of the two conductive members 711a have the same shape. In one embodiment, within a lead frame 71a, the recesses 7114 of the two conductive members 711 have different shapes.

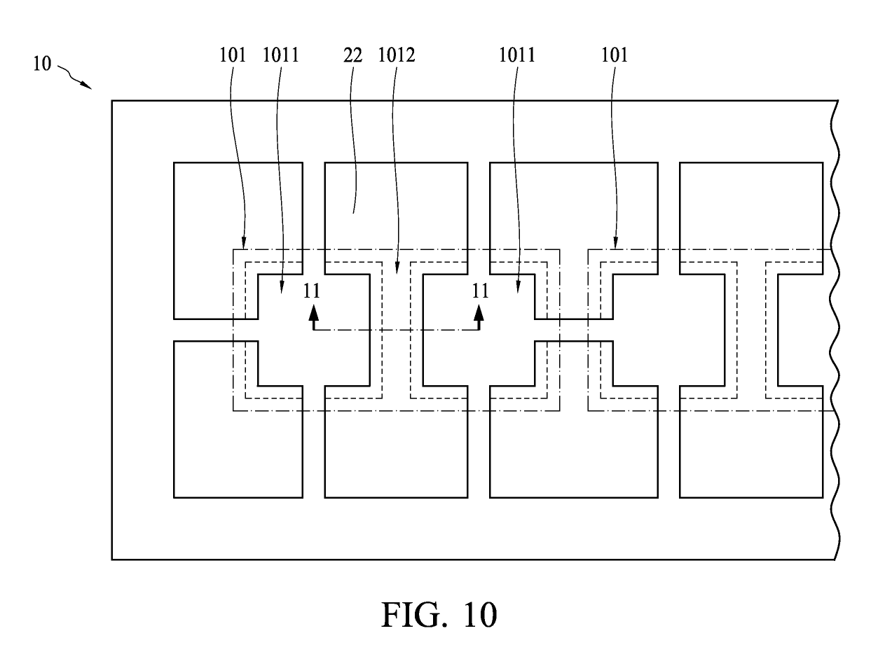

FIG. 10 is a schematic view showing a lead frame strip 10 according to another embodiment of the present invention. As shown in FIG. 10, the lead frame strip 10 can be formed by a stamping process. The lead frame strip 10 comprises a plurality of lead frames 101. Each lead frame 101 comprises two conductive members 1011, which are configured as electrodes for a light-emitting element.

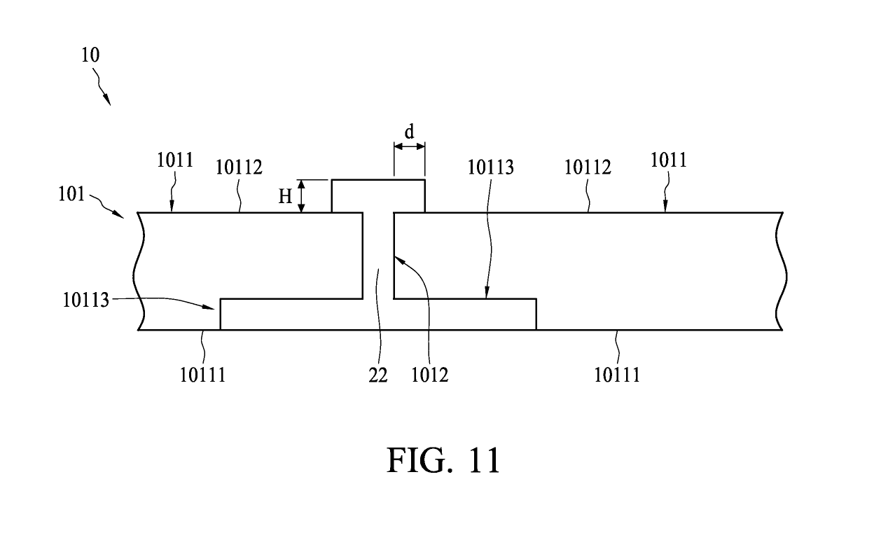

Referring to FIGS. 10 and 11, two conductive members 1011 can be separated by a gap 1012. An adhesive 22 fills the gap 1012 and partially covers a lower surface 10111 and an upper surface 10112 opposite to the lower surface 10111.

The adhesive 22 can protrude from the upper surface 10112 of the lead frame 101. In one embodiment, the adhesive 22 protrudes from the upper surface 10112 to a thickness “H” of not less than ten micrometers. In one embodiment, the adhesive 22 protrudes from the upper surface 10112 to a thickness “H” between 25 micrometers and 35 micrometers. In one embodiment, the adhesive 22 protrudes from the upper surface 10112 to a thickness “H” of not less than 30 micrometers.

Referring to FIG. 10 again, in one embodiment, the adhesive 22 may cover all edge regions of the conductive member 1011. In one embodiment, the adhesive 22 can cover a portion of the edge regions of the conductive member 711 when the bonding strength between the adhesive 22 and the conductive member 711 is sufficient. In one embodiment, the adhesive 22 can cover the part of the edge regions of the conductive member 711 where the ingress of moisture can lead to serious problems.

As shown in FIG. 11, the adhesive 22 extends from the gap 1012 toward the lead frame 101, partially covering the upper surface 10112 of the conductive member 1011. In one embodiment, the adhesive 22 extends from the gap 1012 on the upper surface 10112 to a distance “d” of not less than one micrometer. In one embodiment, the adhesive 22 extends from the gap 1012 on the upper surface 10112 to a distance “d” of not less than five micrometers.

As shown in FIG. 11, a recess 10113 can be formed on the lower surface 10111 of each conductive member 1011. The recess 10113 can have an arbitrary shape. In one embodiment, the recess 10113 can comprise a curve. In one embodiment, the recess 10113 can comprise an arc. In one embodiment, the recess 10113 can be rectangular. In one embodiment, the recess 10113 may comprise a front section and a neck, wherein the neck connects the front section and the gap 1012. In one embodiment, the recess 10113 can have a T shape. In one embodiment, the recess 10113 can have an L shape. In one embodiment, within a lead frame 101, the recesses 10113 on the lower surfaces 10111 of the two conductive members 1011 can have the same shape. In one embodiment, in a lead frame 101, the recesses 10113 on the lower surfaces 10111 of the two conductive members 1011 can have different shapes.

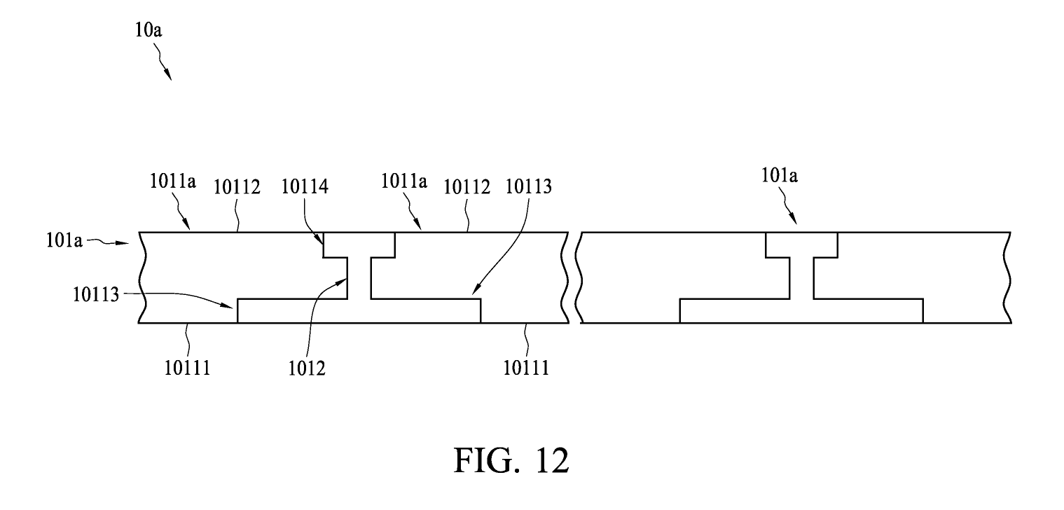

FIG. 12 is a schematic view showing a lead frame strip 10a according to another embodiment of the present invention. The lead frame strip 10a can be formed by a stamping process. As shown in FIG. 12, the lead frame strip 10a may comprise a plurality of lead frames 101a. Each lead frame 101a may comprise two conductive members 1011a. Each conductive member 1011a comprises a lower surface 10111 and an upper surface 10112. A recess 10113 is formed on the lower surface 10111 of each conductive member 1011a and a recess 10114 is formed on the upper surface 10112 of each conductive member 1011a. An adhesive 22 fills the gap 1012 between the two conductive members 1011a and extends to fill the recesses 10113 and 10114.

The recess 10114 can have an arbitrary shape. In one embodiment, the recess 10114 can comprise a curve. In one embodiment, the recess 10114 can comprise an arc. In one embodiment, the recess 10114 can be rectangular. In one embodiment, the recess 10114 can comprise a front section and a neck, wherein the neck connects the front section and the gap 1012. In one embodiment, the recess 10114 has a T shape. In one embodiment, the recess 10114 can have an L shape. In one embodiment, within a lead frame 101a, the recesses 10114 of the two conductive members 1011a can have the same shape. In one embodiment, within a lead frame 101a, the recesses 10114 of the two conductive members 1011a can have different shapes.

The adhesion between the adhesive and the lead frame of a light-emitting device or a lead frame strip of some embodiments of the present invention can be significantly improved. In some embodiments of the present invention, a light-emitting device or a lead frame strip provides a longer path for moisture penetration along the interface of the adhesive and the lead frame.

It will be apparent to those skilled in the art that various modifications can be made to the disclosed embodiments. It is intended that the specification and examples be considered as exemplary only, with the true scope of the disclosure being indicated by the following claims and their equivalents.

What is claimed is:

1. A light-emitting device comprising:
a lead frame comprising two conductive members separated by a gap, wherein each conductive member comprises an upper surface and a lower surface opposite to the upper surface;
an adhesive filling the gap and partially covering the upper and lower surfaces of each conductive member; and
a light-emitting element disposed on the upper surface of one conductive member of the two conductive members, electrically connecting the two conductive members.

2. The light-emitting device of claim 1, wherein the adhesive protrudes from the upper surface of each conductive member to a thickness of not less than ten micrometers.

3. The light-emitting device of claim 1, wherein the adhesive protrudes from the upper surface of each conductive member to a thickness in a range of from 25 micrometers to 35 micrometers.

4. The light-emitting device of claim 1, wherein the adhesive protrudes from the upper surface of each conductive member to a thickness of not less than 30 micrometers.

5. The light-emitting device of claim 1, wherein the adhesive extends from the gap onto the upper surface of each conductive member to a distance of not less than one micrometer.

6. The light-emitting device of claim 1, wherein the adhesive extends from the gap onto the upper surface of each conductive member to a distance of not less than five micrometers.

7. The light-emitting device of claim 1, wherein the upper surface of each conductive member comprises a recess, and the adhesive on the upper surface fills the recess.

8. The light-emitting device of claim 7, wherein the recess extends along the gap.

9. The light-emitting device of claim 7, wherein the recess comprises a front section and a neck, wherein the neck connects the front section and the gap.

10. The light-emitting device of claim 7, wherein the recess has a T shape.

11. The light-emitting device of claim 1, wherein the lower surface of each conductive member comprises a recess, and the adhesive on the lower surface fills the recess.

12. The light-emitting device of claim 11, wherein the recess of the lower surface comprises a front section and a neck, wherein the neck connects the front section and the gap.

13. The light-emitting device of claim 11, wherein the recess of the lower surface comprises a T shape.

14. The light-emitting device of claim 1, further comprising a reflector disposed on the lead frame.

15. The light-emitting device of claim 1, wherein the adhesive comprises a resin or silicone.

16. A lead frame strip comprising:
a plurality of lead frames each comprising:
two conductive members separated by a gap, wherein each conductive member comprises an upper surface and a lower surface opposite to the upper surface; and
an adhesive filling the gap between the two conductive members of each lead frame and partially covering the upper and lower surfaces of each conductive member of each lead frame.

17. The lead frame strip of claim 16, wherein the adhesive protrudes from the upper surface of each conductive member to a thickness of not less than ten micrometers.

18. The lead frame strip of claim 16, wherein the adhesive protrudes from the upper surface of each conductive member to a thickness in a range of from 25 micrometers to 35 micrometers.

19. The lead frame strip of claim 16, wherein the adhesive protrudes from the upper surface of each conductive member to a thickness of not less than 30 micrometers.

20. The lead frame strip of claim 16, wherein the adhesive extends from the gap onto the upper surface of each conductive member to a distance of not less than one micrometer.

21. The lead frame strip of claim 16, wherein the adhesive extends from the gap onto the upper surface of each conductive member to a distance of not less than five micrometers.

22. The lead frame strip of claim 16, wherein the upper surface of each conductive member comprises a recess, and the adhesive on the upper surface fills the recess.

23. The lead frame strip of claim 22, wherein the recess extends along the gap.

24. The lead frame strip of claim 22, wherein the recess comprises a front section and a neck, wherein the neck connects the front section and the gap.

25. The lead frame strip of claim 22, wherein the recess has a T shape.

26. The lead frame strip of claim 16, wherein the lower surface of each conductive member comprises a recess, and the adhesive on the lower surface fills the recess.

27. The lead frame strip of claim 26, wherein the recess of the lower surface comprises a front section and a neck, wherein the neck connects the front section and the gap.

28. The lead frame strip of claim 26, wherein the recess of the lower surface comprises a T shape.

29. The lead frame strip of claim 16, wherein the adhesive comprises a resin or silicone.
